(19) United States
(12) Patent Application Publication
(10) Pub. No.: US 2026/0299411 A1
(43) Pub. Date: Oct. 1, 2026

(54) PHOTOSENSITIVE RESIN COMPOSITION, RESIN FILM HAVING PATTERN, METHOD FOR PRODUCING RESIN FILM HAVING PATTERN, AND SEMICONDUCTOR CIRCUIT BOARD

(71) Applicant: JSR CORPORATION, Tokyo (JP)

(72) Inventors: Ryuichi OKUDA, Minato-ku, Tokyo (JP); Takashi DOI, Minato-ku, Tokyo (JP); Ryoji TATARA, Minato-ku, Tokyo (JP); Hirokazu ITO, Minato-ku, Tokyo (JP)

(73) Assignee: JSR CORPORATION, Tokyo (JP)

(21) Appl. No.: 18/874,154

(22) PCT Filed: Apr. 10, 2023
(86) PCT No.: PCT/JP2023/014564

§ 371 Date: Dec. 12, 2024

(30) Foreign Application Priority Data
Jun. 14, 2022 (JP) 2022-095999

(51) Int. Cl. G03F 7/023; G03F 7/20; H10W 70/695

(52) U.S. Cl. CPC G03F 7/0233; G03F 7/20; H10W 70/695

(57) ABSTRACT

A photosensitive resin composition includes a polymer (A) which is at least one type selected from a group consisting of a polyimide and a polyimide precursor and includes a structural unit (a) including a structural unit derived from an acid anhydride represented by formula (1) and a structural unit (b) derived from a diamine, a naphthoquinonediazide compound (B), a crosslinking compound (C1) having a methylol group or an alkoxymethyl group, and a solvent (D). L represents, for example, a single bond, R¹ to R³ represent, for example, a hydrogen atom, or an alkylene group formed by bonding R¹ and R² (or R³) in the same ring to each other, n¹ to n² represent an integer of 0 to 3, and Y¹ represents a structure represented by, for example, a formula (Y1): (—Ar¹—).

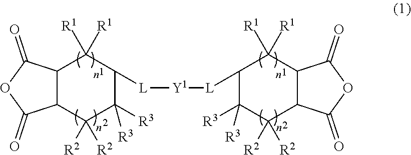

### TECHNICAL FIELD

One aspect of the present invention relates to a photosensitive resin composition, a resin film having a pattern, a method for producing a resin film having a pattern, and a semiconductor circuit board.

### BACKGROUND ART

Conventionally, various photosensitive resin compositions have been proposed as materials used for forming, for example, a surface protective film and an interlayer insulation film used for a semiconductor circuit board in an electronic component. For example, a photosensitive resin composition including a resin having a phenolic hydroxy group as an alkali-soluble resin has been studied (Patent Literatures 1 and 2).

### CITATION LIST

### Patent Literature

Patent Literature 1: JP 2014-186300 A
Patent Literature 2: JP 2013-210606 A

### SUMMARY OF INVENTION

### Technical Problem

A package technology using a silicon interposer or a fan-out type package technology using a mold substrate, for example, has been proposed to increase a density and performance of a semiconductor circuit board. However, since a substrate material and an insulation film have different coefficients of linear thermal expansion, warpage deformation may easily occur due to, for example, a temperature change in a manufacturing process of the semiconductor circuit board or the use environment of the information terminal device. In a case where the insulation film has small elongation properties, there is a problem that the insulation film cannot withstand the warpage deformation and is thus damaged. In addition, also in an environmental load test (for example, PCT test) assuming a use environment of the information terminal device, high reliability capable of maintaining elongation properties is required.

Furthermore, the insulation film used in the semiconductor circuit board is used between fine pitch electrode pads or between wirings. Therefore, a composition for forming a resin film having a pattern such as an insulation film (hereinafter, also referred to as a “patterned resin film”) is required to have photolithographic properties capable of patterning by exposure and development.

The present invention has been made to solve the above problems, and an object of the present invention is to provide a photosensitive resin composition that is capable of forming a resin film having excellent elongation properties and high PCT resistance, and that has excellent photolithographic properties, to provide a patterned resin film that has excellent elongation properties and high PCT resistance, and a method for producing the same, and to provide a semiconductor circuit board including a patterned resin film that has excellent elongation properties and high PCT resistance.

### Solution to Problem

The present inventors have conducted intensive studies in order to solve the above problems. As a result, the present inventors have found that the above problems can be solved by a photosensitive resin composition including a polymer having a specific structural unit, a specific photoacid generator, and a specific crosslinking agent, and have completed the present invention. Examples of aspects of the present invention are shown below.

[1]

A photosensitive resin composition including:
(A) a polymer that is at least one type selected from a group consisting of a polyimide and a polyimide precursor;
(B) a naphthoquinonediazide compound;
(C1) a crosslinking compound having a methylol group or an alkoxymethyl group; and
(D) a solvent, in which
the polymer (A) includes a structural unit (a) derived from an acid anhydride and a structural unit (b) derived from a diamine, and
the structural unit (a) includes a structural unit (a1) derived from an acid anhydride represented by a formula (1) below.

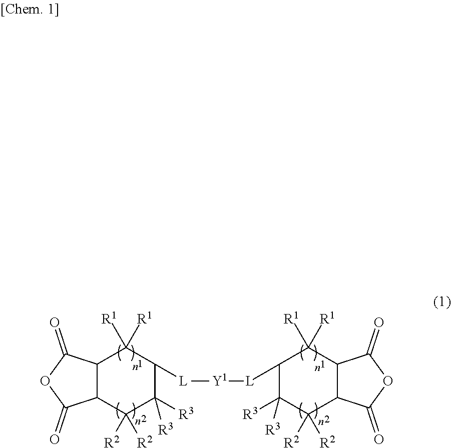

In the formula (1),
L's independently represent a single bond, an ester bond, or an amide bond,
R¹, R², and R³ each independently represent a hydrogen atom or an alkyl group having 1 to 6 carbon atoms, or an alkylene group having 1 to 4 carbon atoms formed by bonding R¹ and R² or R¹ and R³ in a same ring to each other,
n¹ and n² each independently represent an integer of 0 to 3 (provided that, in the same ring, at least one of n¹ and n² is an integer of 1 or more),
Y¹ represents a structure represented by a formula (Y1) or (Y2) below:

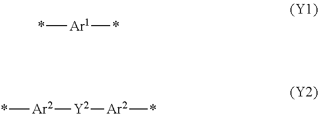

in the formulas (Y1) and (Y2), * represents a bond to L in the formula (1),
Ar¹ and Ar² each independently represent an unsubstituted aromatic ring or a group obtained by removing two hydrogen atoms on an aromatic ring from an aromatic ring substituted with an alkyl group or an alkoxy group having 1 to 6 carbon atoms, and
Y² in the formula (Y²) is at least one type of group selected from a group consisting of a single bond, an oxygen atom, a sulfur atom, a sulfonyl group, a carbonyl group, a methylene group, a dimethylmethylene group, and a bis(trifluoromethyl)methylene group.

[2]

The photosensitive resin composition according to [1], in which the polymer (A) has a phenolic hydroxy group at a polymer terminal.

[3]

The photosensitive resin composition according to [1] or [2], in which the structural unit (b) derived from a diamine includes a structural unit (b1) derived from a diamine having a phenolic hydroxy group.

[4]

The photosensitive resin composition according to any one of [1] to [3], further including an epoxy-based compound (C2) (which is different from the crosslinking compound (C1)).

[5]

A method for producing a resin film having a pattern, the method including: a step (1) of forming, on a substrate, a coating film of the photosensitive resin composition according to any one of [1] to [4]; a step (2) of selectively exposing the coating film; and a step (3) of developing the coating film after exposure with an alkaline developer.

[6]

A resin film having a pattern obtained by curing the photosensitive resin composition according to any one of [1] to [4].

[7]

A semiconductor circuit board including the resin film having a pattern according to [6].

### Advantageous Effects of Invention

According to an aspect of the present invention, it is possible to provide a photosensitive resin composition that is capable of forming a resin film having excellent elongation properties and high PCT resistance, and that has excellent photolithographic properties, and to provide a patterned resin film that has excellent elongation properties and high PCT resistance, and a method for producing the same, and to provide a semiconductor circuit board including a patterned resin film that has excellent elongation properties and high PCT resistance.

### DESCRIPTION OF EMBODIMENTS

Hereinafter, embodiments for carrying out the present invention will be described in detail including preferred embodiments.

### [Photosensitive Resin Composition]

A photosensitive resin composition according to an aspect of the present invention (hereinafter also simply referred to as the “present composition”) includes:
(A) a polymer that is at least one type selected from a group consisting of a polyimide and a polyimide precursor (hereinafter also referred to as “polymer (A)”);
(B) a naphthoquinonediazide compound (hereinafter also referred to as “compound (B)”),
(C1) a crosslinking compound having a methylol group or an alkoxymethyl group (hereinafter also referred to as “crosslinking compound (C1)”); and
(D) a solvent.

### <Polymer (A)>

The polymer (A) included in the present composition is a polymer (resin) that is at least one type selected from the group consisting of a polyimide and a polyimide precursor, and includes a structural unit (a) derived from an acid anhydride and a structural unit (b) derived from a diamine. Since the polymer (A) contains such a structure, the polymer (A) included in the present composition can have both high i-line transmittance and high elongation rate. In addition, the polymer (A) has excellent solvent solubility, and it is also possible to impart alkali solubility by introducing an alkali-soluble group.

### (Structural Unit (a))

The structural unit (a) is a structural unit derived from an acid anhydride and includes a structural unit (a1) derived from an acid anhydride represented by the following formula (1). It is considered that the acid anhydride group having an alicyclic structure in the structural unit (a1) contributes to improvement of i-line transmittance, solvent solubility, and PCT resistance, and the aromatic group contributes to improvement of elongation rate. When the polymer (A) includes the structural unit (a1), the present composition has both high i-line transmittance and high elongation rate. As the structural unit (a1), one type or two or more types may be included.

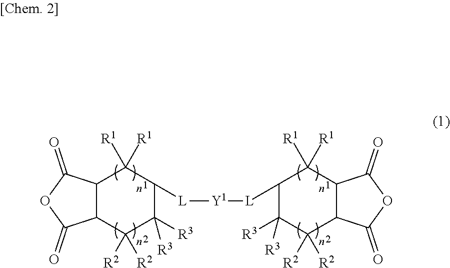

In the formula (1), Y¹ represents a structure represented by the following formula (Y1) or (Y2), and is preferably a structure represented by the following formula (Y1). In the following formula, * represents a bond to L in the formula (1).

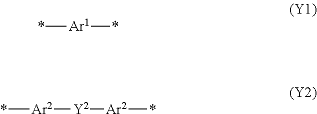

In the formulas (Y1) and (Y2), Ar¹ and Ar² each independently represent an unsubstituted aromatic ring or a group obtained by removing two hydrogen atoms on an aromatic ring from an aromatic ring substituted with an alkyl group or an alkoxy group having 1 to 6 carbon atoms.

Examples of the aromatic ring include aromatic hydrocarbon compounds such as a benzene ring and a naphthalene ring and heteroaromatic compounds such as a furan ring and a pyrrole ring, and aromatic hydrocarbon compounds having 6 to 10 carbon atoms such as a benzene ring and a naphthalene ring are preferable.

Examples of the alkyl group having 1 to 6 carbon atoms include a methyl group, an ethyl group, a n-propyl group, an isopropyl group, a n-butyl group, a n-pentyl group, and a n-hexyl group. Examples of the alkoxy group having 1 to 6 carbon atoms include a methoxy group and an ethoxy group. Among these, an alkyl group having 1 or 2 carbon atoms such as a methyl group or an ethyl group, or an alkoxy group having 1 or 2 carbon atoms such as a methoxy group or an ethoxy group is preferable.

In the formula (Y2), Y² is at least one type of group selected from the group consisting of a single bond, an oxygen atom, a sulfur atom, a sulfonyl group, a carbonyl group, a methylene group, a dimethylmethylene group, and a bis(trifluoromethyl)methylene group.

In the formula (1), L independently represents a single bond, an ester bond, or an amide bond, the ester bond includes either bond represented by —O—C(O)— or —C(O)—O—, and the amide bond includes either bond represented by —NH—C(O)— or —C(O)—NH—.

In the formula (1), R¹, R², and R³ each independently represent a hydrogen atom or an alkyl group having 1 to 6 carbon atoms, or an alkylene group having 1 to 4 carbon atoms formed by bonding R¹ and R² or R¹ and R³ in the same ring to each other. Examples of the alkyl group having 1 to 6 carbon atoms include those similar to the alkyl groups described above, and a methyl group and an ethyl group are preferable.

In the formula (1), n¹ and n² each independently represent an integer of 0 to 3, and is preferably 0 or 1. Provided that, in the same ring, at least one of n¹ and n² is an integer of 1 or more.

As the acid anhydride represented by the formula (1), R¹ to R³ in the formula (1) are preferably all hydrogen atoms, or an alkylene group having 1 or 2 carbon atoms formed by bonding one R¹ and one R² or one R¹ and one R³ in the same ring to each other. Preferable specific examples of the acid anhydride represented by the formula (1) include acid anhydrides represented by the following formulas (1-1) to (1-3), and an acid anhydride represented by the following formula (1-1) or (1-2) is more preferable.

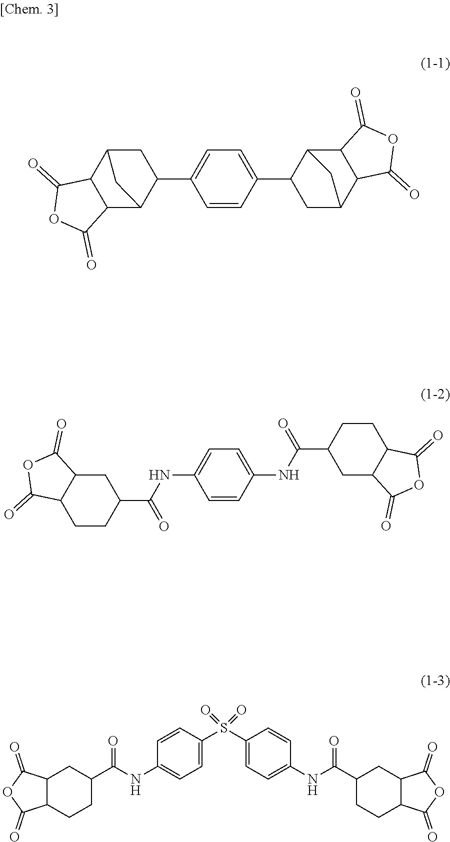 [SMILES: O=C1OC(=O)C2C3CC(CC3c3ccc(C4CC5CC4C4C(=O)OC(=O)C54)cc3)C12 ; O=C(Nc1ccc(NC(=O)C2CCC3C(=O)OC(=O)C3C2)cc1)C1CCC2C(=O)OC(=O)C2C1 ; O=C(Nc1ccc(S(=O)(=O)c2ccc(NC(=O)C3CCC4C(=O)OC(=O)C4C3)cc2)cc1)C1CCC2C(=O)OC(=O)C2C1]

The structural unit (a) may include a structural unit (a2) derived from an acid anhydride other than the acid anhydride represented by the formula (1) as long as the effect of the present invention is not impaired, and as the structural unit (a2), one type or two or more types may be included.

As the acid anhydride other than the acid anhydride represented by the formula (1) (hereinafter also referred to as “another acid anhydride”), an acid anhydride represented by the following formula (2) is preferable.

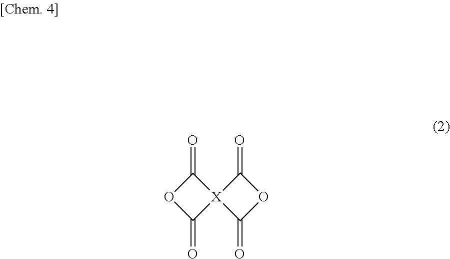

In the formula (2), examples of X include groups represented by the following formulas. In the following formulas, * represents a bond to a carbon atom to which X in the formula (2) is bonded.

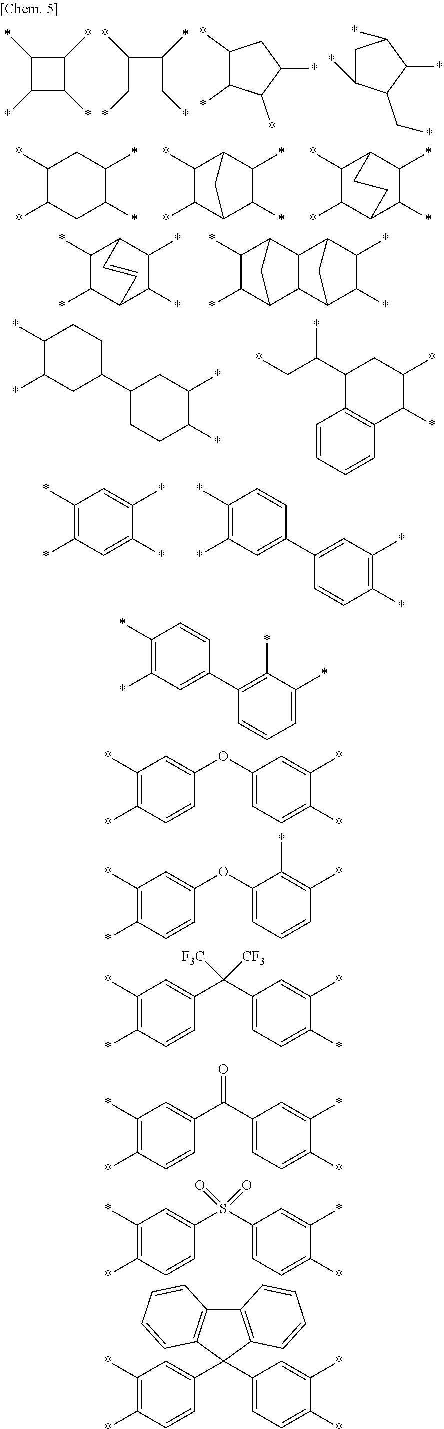

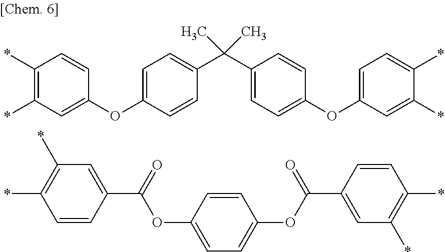

A hydrogen atom (omitted in the formula) in the group represented by the formula may be substituted with, for example, an alkyl group or alkoxy group having 1 to 6 carbon atoms, or a group in which a hydrogen atom in the alkyl group or alkoxy group is substituted with a halogen atom (for example, a trifluoromethyl group).

When the polymer (A) includes the structural unit (a2), the content molar ratio of the structural unit (a1) to the structural unit (a2) (structural unit (a1)/structural unit (a2)) is preferably 99/1 to 50/50, and more preferably 95/5 to 60/40. The content ratio of each structural unit can be measured by ¹³C-NMR. When the content molar ratio of the structural unit (a1) to the structural unit (a2) is within the above range, the above-mentioned effect of using the structural unit (a1) is easily obtained. The polymer in which the content molar ratio of each monomer (such as an acid anhydride, a diamine described later, and a terminal modifier described later) in the monomer mixture is within the above range can be said to be a polymer in which the content molar ratio of the structural unit derived from each monomer is within the above range.

### (Structural Unit (b))

The structural unit (b) is a structural unit derived from a diamine. The structural unit (b) is not particularly limited as long as it is a structural unit derived from a diamine, but preferably includes a structural unit derived from a diamine having a hydroxy group, and more preferably includes a structural unit (b1) derived from a diamine having a phenolic hydroxy group. As the structural unit (b1), one type or two or more types may be included.

The diamine having a hydroxy group is preferably a diamine represented by the following formula (3).

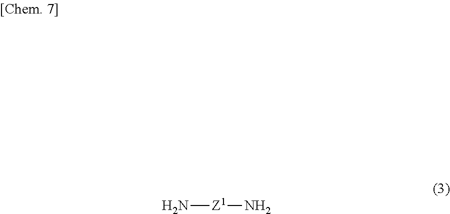

In the formula (3), Z¹ represents a divalent group having a hydroxy group, and is preferably a divalent group represented by the following formula (Z1) or (Z2). In the following formulas, * represents a bond to a nitrogen atom to which Z¹ in the formula (3) is bonded.

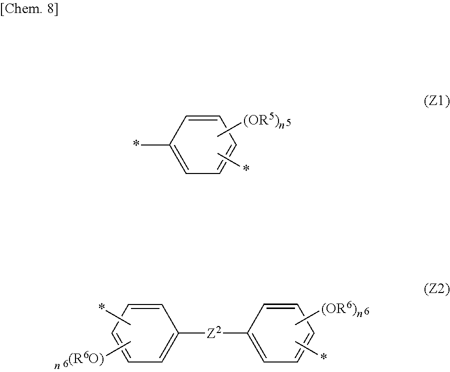

R⁵ and R⁶ in the formulas (Z1) and (Z2) each independently represent a hydrogen atom, an acyl group, or an alkyl group. Preferable examples of the acyl group include a formyl group, an acetyl group, a propionyl group, a butyroyl group, and an isobutyroyl group, and preferable examples of the alkyl group include a methyl group, an ethyl group, a n-propyl group, an isopropyl group, a n-butyl group, a n-pentyl group, a n-hexyl group, a n-octyl group, a n-decyl group, and a n-dodecyl group.

Z² in the formula (Z2) is at least one type of group selected from the group consisting of a single bond, an oxygen atom, a sulfur atom, a sulfonyl group, a carbonyl group, a methylene group, a dimethylmethylene group, and a bis(trifluoromethyl)methylene group.

In the formula (Z1), n⁵ is an integer of 1 or 2.

In the formula (Z2), n⁶'s are each independently an integer of 0 to 2, and at least one of two n⁶'s is an integer of 1 or more.

When there is one OR⁵ group (or OR⁶ group) in one molecule of the diamine represented by the formula (3), R⁵ (or R⁶) is a hydrogen atom, and when there is a plurality of OR⁵ groups (or OR⁶ groups) in one molecule, at least one of R⁵'s (or R⁶'s) is a hydrogen atom. From this, the diamine represented by the formula (3) having the group represented by the formula (Z1) or (Z2) is a diamine having a phenolic hydroxy group and gives the structural unit (b1).

Among the diamines represented by the formula (3) having a group represented by the formula (Z1), it is preferable that Z¹ in the formula (3) is specifically a divalent group shown below. In the following formulas, * represents a bond to a nitrogen atom to which Z¹ in the formula (3) is bonded.

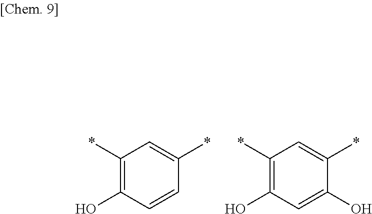

Among the diamines represented by the formula (3) having a group represented by the formula (Z2), it is preferable that Z¹ in the formula (3) is specifically a divalent group shown below. In the following formulas, represents a bond to a nitrogen atom to which Z¹ in the formula (3) is bonded.

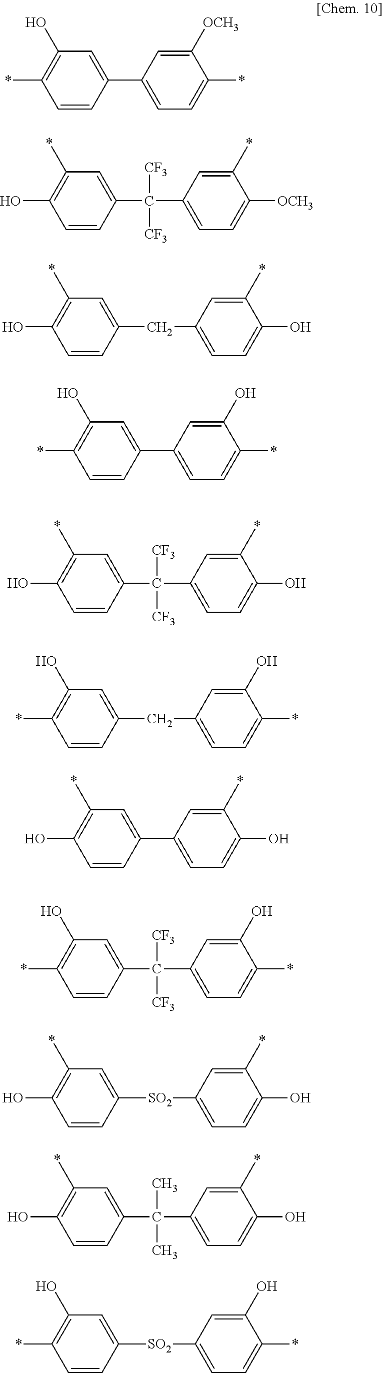

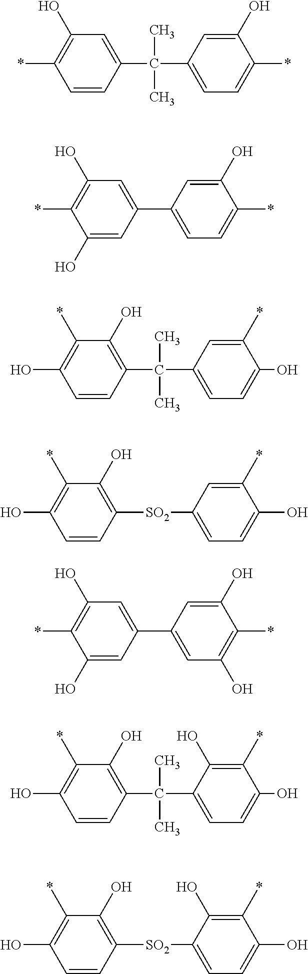

In addition, examples of the diamine having a phenolic hydroxy group among the diamines represented by the formula (3) other than the diamine represented by the formula (3) having a group represented by the formula (Z1) or (Z2) include diamines in which Z¹ in the formula (3) is a divalent group shown below. In the following formulas, * represents a bond to a nitrogen atom to which Z¹ in the formula (3) is bonded.

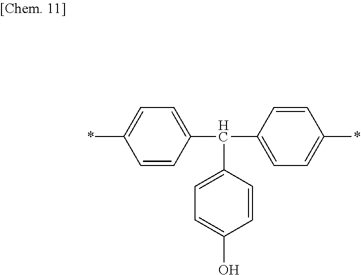 [SMILES: *c1ccc(C(c2ccc(*)cc2)c2ccc(O)cc2)cc1]

The structural unit (b) can include a structural unit (b2) derived from a diamine other than a diamine having a phenolic hydroxy group. As the structural unit (b2), one type or two or more types may be included.

Examples of the diamine other than the diamine having a phenolic hydroxy group include, diamines having no phenolic hydroxy group among the diamines represented by the formula (3); aromatic diamines such as p-phenylenediamine, m-phenylenediamine, 4,4′-diaminodiphenylmethane, 4,4′-diaminodiphenylethane, 4,4′-diaminodiphenyl sulfide, 4,4′-diaminodiphenyl sulfone, 3,3′-dimethyl-4,4′-diaminobiphenyl, 4,4′-diaminobenzanilide, 4,4′-diaminodiphenyl ether, 1,5-diaminonaphthalene, 2,2′-dimethyl-4,4′-diaminobiphenyl, 5-amino-1-(4′-aminophenyl)-1,3,3-trimethylindane, 6-amino-1-(4′-aminophenyl)-1,3,3-trimethylindane, 3,4′-diaminodiphenyl ether, 3,3′-diaminobenzophenone, 3,4′-diaminobenzophenone, 4,4′-diaminobenzophenone, 1,3-bis(4-aminophenoxy) propane, 1,4-bis(4-aminophenoxy) butane, 1,5-bis(4-aminophenoxy) pentane, 1,6-bis(4-aminophenoxy) hexane, 2,2-bis[4-(4-aminophenoxy)phenyl]propane, 2,2-bis[4-(4-aminophenoxy)phenyl]hexafluoropropane, 2,2-bis(4-aminophenyl) hexafluoropropane, bis[4-(4-aminophenoxy)phenyl]sulfone, 1,4-bis(4-aminophenoxy)benzene, 1,3-bis(4-aminophenoxy)benzene, 1,3-bis(3-aminophenoxy)benzene, 9,9-bis(4-aminophenyl)-10-hydroanthracene, 2,7-diaminofluorene, 9,9-bis(4-aminophenyl) fluorene, 4,4′-methylene-bis(2-chloroaniline), 2,2′,5,5′-tetrachloro-4,4′-diaminobiphenyl, 2,2′-dichloro-4,4′-diamino-5,5′-dimethoxybiphenyl, 3,3′-dimethoxy-4,4′-diaminobiphenyl, 1,4,4′-(p-phenyleneisopropylidene)bisaniline, 4,4′-(m-phenyleneisopropylidene)bisaniline, 2,2′-bis[4-(4-amino-2-trifluoromethylphenoxy)phenyl]hexafluoropropane, 4,4′-bis(4-aminophenoxy) biphenyl, 4,4′-diamino-2,2′-bis(trifluoromethyl) biphenyl, and 4,4′-bis[(4-amino-2-trifluoromethyl) phenoxy]-octafluorobiphenyl; aliphatic or alicyclic diamines such as meta-xylylenediamine, para-xylylenediamine, 1,3-propanediamine, tetramethylenediamine, pentamethylenediamine, hexamethylenediamine, heptamethylenediamine, octamethylenediamine, nonamethylenediamine, decamethylenediamine, dodecamethylenediamine, 4,4′-diaminoheptamethylenediamine, 1,4-diaminocyclohexane, 1,3-bis(aminomethyl)cyclohexane, 1,4-bis(aminomethyl)cyclohexane, isophoronediamine, tetrahydrodicyclopentadienylenediamine, hexahydro-4,7-methanoindanylenedimethylenediamine, tricyclo[6.2.1.02,7]-undecylenedimethyldiamine, and 4,4′-methylenebis(cyclohexylamine); siloxane-containing diamines such as 1,3-bis(3-aminopropyl)tetramethyldisiloxane; polyether diamines; and polyoxyalkylenediamines.

When the polymer (A) includes the structural unit (b2), the content molar ratio of the structural unit (b1) to the structural unit (b2) (structural unit (b1)/structural unit (b2)) is preferably 99/1 to 50/50, and more preferably 90/10 to 50/50. The content ratio of each structural unit can be measured by 13C-NMR. When the content molar ratio of the structural unit (b1) to the structural unit (b2) is within the above range, the above-mentioned effect of using the structural unit (b1) is easily obtained. The polymer in which the content molar ratio of each monomer in the monomer mixture is within the above range can be said to be a polymer in which the content molar ratio of the structural unit derived from each monomer is within the above range.

### (Terminal Structure)

The polymer (A) used in the present composition preferably has a phenolic hydroxy group at the polymer terminal. Usually, a method for introducing phenol into a polymer terminal is achieved using a terminal modifier having a phenolic hydroxy group as a terminal modifier. Examples of the terminal modifier include 2-aminophenol, 3-aminophenol, and 4-aminophenol. These modify the polymer terminal from the acid anhydride by causing an acid anhydride terminal in the polymer (A) and an amine in the terminal modifier to react with each other.

In the present invention, when a diamine having a phenolic hydroxy group as described above is used as the monomer, a polymer having a phenolic hydroxy group at the polymer terminal can also be synthesized without using a terminal modifier.

In the case of using the terminal modifier, the molar ratio (mol %) of the terminal modifier when the total molar amount of the acid anhydride that gives the structural unit (a), the diamine that gives the structural unit (b), and the terminal modifier is assumed to be 100 (terminal modifier×100/(acid anhydride+diamine+ terminal modifier)) is preferably 1 to 20 mol %, and more preferably 5 to 15 mol %.

### (Characteristics of Polymer (A))

The content molar ratio of the structural unit (a) to the structural unit (b) in the polymer (A) (structural unit (a)/structural unit (b)) is preferably 60/40 to 40/60, and more preferably 55/45 to 45/55. The content ratio of each structural unit can be measured by 13C-NMR. The polymer in which the content molar ratio of each monomer in the monomer mixture is within the above range can be said to be a polymer in which the content molar ratio of the structural unit derived from each monomer is within the above range.

The polymer (A) preferably has a polystyrene equivalent weight average molecular weight (hereinafter also referred to as “Mw”) as measured by gel permeation chromatography (GPC) of about 2,000 to 800,000. When the polymer (A) is used in the photosensitive resin composition, the Mw is preferably about 2,000 to 100,000, more preferably about 2,000 to 70,000, and still more preferably about 3,000 to 50,000. In the case of using the polymer (A) in the photosensitive resin composition, when the Mw is less than 2,000, there is a tendency that sufficient mechanical characteristics as an insulation film cannot be obtained. Meanwhile, when the Mw is more than 100,000, the solubility of the exposed portion of the photosensitive resin composition obtained using the polymer (A) in a solvent or a developer tends to be poor.

In addition, the resin film obtained from the polymer (A) has excellent elongation properties, PCT resistance, and i-line transmittance. Therefore, it is considered that the patterned resin film obtained by curing the present composition using the polymer (A) has excellent elongation properties, PCT resistance, and photolithographic properties.

As the polymer (A), one type can be used or two or more types can be used in combination.

A lower limit value of the content ratio of the polymer (A) in 100 mass % of the solid content of the present composition is usually 20 mass %, preferably 40 mass %, and more preferably 60 mass %, and an upper limit value thereof is usually 99 mass % and preferably 95 mass %. Note that the solid content refers to all components other than the solvent (D) described later that can be included in the present composition.

The polymer (A) has at least one type of structure selected from the group consisting of a polyimide and a polyimide precursor. The polyimide precursor includes a polyamic acid and a polyamic acid ester. The structure of the polymer (A) can be checked by, for example, ¹H-NMR.

### (Method for Producing Polymer (A))

The polymer (A) can be obtained by, for example, causing a reaction in a polymerization solvent to synthesize a polyamic acid using an acid anhydride represented by the formula (1), a diamine (for example, a diamine having a phenolic hydroxy group), and if necessary, an acid anhydride and a diamine other than those described above, and a terminal modifier, and further causing an imidization reaction to synthesize a polyimide. The terminal modifier can be allowed to react before the polyamic acid synthesis, during the polyamic acid synthesis, or after the imidization reaction depending on the introduction site (main chain terminal or side chain terminal). At this time, the polyamic acid synthesized during the process can be the polymer (A) having the polyimide precursor structure described above. In addition, a polyamic acid ester obtained by esterifying a polyamic acid according to a known method can also be the polymer (A) having the polyimide precursor structure described above.

At this time, as a synthesis procedure of a polyamic acid for obtaining a polyimide, for example, the following two types of methods can be applied, and the synthesis may be performed by either method. That is, the methods are (i) a method in which an acid anhydride is dissolved in a polymerization solvent and then a diamine is allowed to react, and (ii) a method in which a diamine is dissolved in a polymerization solvent and then an acid anhydride is allowed to react.

As the polymerization solvent, one that can dissolve raw materials and a product at the time of synthesis of the polymer (A) is selected. As the polymerization solvent, it is preferable to use at least one type selected from the group consisting of N-methyl-2-pyrrolidone, 1,3-dimethyl-2-imidazolidinone, and γ-butyrolactone. These compounds can be used alone as the polymerization solvent, or two or more types thereof can be used in admixture.

In addition to the polymerization solvent, another solvent can be used in combination as needed. Examples of the another solvent include diethylene glycol dialkyl ethers such as diethylene glycol dimethyl ether and diethylene glycol diethyl ether; ethylene glycol monoalkyl ether acetates such as ethylene glycol monomethyl ether acetate; diethylene glycol monoalkyl ether acetates such as diethylene glycol monomethyl ether acetate; propylene glycol monoalkyl ether acetates such as propylene glycol monomethyl ether acetate; ketones such as methyl ethyl ketone and cyclohexanone; alcohols such as methanol, ethanol, and propanol; ether solvents such as diglyme and triglyme; and aromatic hydrocarbons such as toluene and xylene.

As the imidization reaction for obtaining the polymer (A) having a polyimide structure, known methods such as a heating imidization reaction and a chemical imidization reaction can be applied. When the polymer (A) is synthesized by a heating imidization reaction, the polymer (A) is preferably synthesized by heating a synthesis solution of a polyamic acid at 120 to 210° C. for 1 to 16 hours. If necessary, the reaction may be performed while water in the system is removed using an azeotropic solvent such as toluene or xylene.

### <Compound (B)>

The present composition includes a naphthoquinonediazide compound (B).

The compound (B) is a compound that functions as a photoacid generator and generates an acid by a treatment including light irradiation. By the exposure treatment of the resin film formed from the present composition, an acid is generated in the exposed portion based on the compound (B), and the solubility of the exposed portion in an alkaline developer changes based on the action of the acid.

The compound (B) generates a carboxylic acid by a treatment including light irradiation and development using an alkaline developer. The resin film obtained from the composition including the compound (B) is a film hardly soluble in an alkaline developer. Therefore, a positive pattern can be formed using the compound (B).

The compound (B) is, for example, an ester compound of a compound having one or more phenolic hydroxy groups and 1,2-naphthoquinonediazide-4-sulfonic acid or 1,2-naphthoquinonediazide-5-sulfonic acid. Specific examples of the compound having one or more phenolic hydroxy groups include compounds described in paragraphs to of JP 2014-186300 A, and these compounds shall be described herein.

As the compound (B), one type can be used or two or more types can be used in combination.

In the present composition, the content of the compound (B) is usually 5 to 50 parts by mass, preferably 10 to 40 parts by mass, and more preferably 15 to 35 parts by mass with respect to 100 parts by mass of the polymer (A). When the content of the compound (B) is the above lower limit value or more, the residual film rate of the unexposed portion is improved, and an image that is faithful to a pattern mask is easily obtained. When the content of the compound (B) is the above upper limit value or less, a resin film having an excellent pattern shape is easily obtained, and there is a tendency that foaming during film formation can be prevented.

### <Crosslinking Agent (C)>

The present composition includens a crosslinking agent (C) for improving the curability of a resin film, and for achieving both chemical resistance and crack resistance of a cured film. The crosslinking agent (C) acts as a crosslinking component (curing component) that reacts with the polymer (A) or reacts between the crosslinking agents. As the crosslinking agent (C), one type can be used or two or more types can be used in combination.

The present composition includes a crosslinking compound (C1) having a methylol group or an alkoxymethyl group as the crosslinking agent (C). The crosslinking compound (C1) used in the present composition includes only a methylol group or an alkoxymethyl group as a crosslinkable group, and does not include a crosslinking compound containing another crosslinkable group such as an epoxy group (oxirane ring). As the crosslinking agent (C1), one type can be used or two or more types can be used in combination.

The methylol group or alkoxymethyl group is a group represented by —CH₂OR.

In the formula, R is a hydrogen atom, an alkyl group having 1 to 10 carbon atoms, or an acyl group having 2 to 10 carbon atoms, preferably a hydrogen atom or an alkyl group having 1 to 6 carbon atoms. Examples of the alkyl group include a methyl group, an ethyl group, a propyl group, and a butyl group. Examples of the acyl group include an acetyl group. Here, it is considered that in the group represented by —CH₂OR, a methylene group is activated by an acid, and the reactivity with the phenolic hydroxy group of the polymer (A) or its ortho position is high, so that the crosslinking reaction easily proceeds.

Examples of the crosslinking compound (C1) include a methylol group-containing phenol compound, an alkylmethylol group-containing phenol compound, and an acyloxymethyl group-containing phenol compound, and specifically, compounds shown below are preferable.

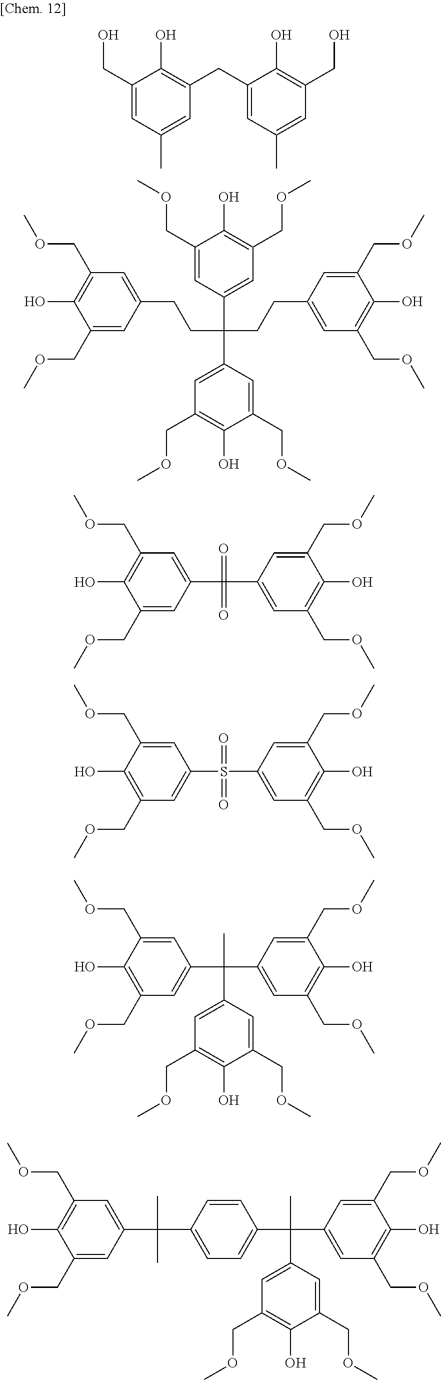

Examples of the crosslinking compound (C1) other than the above compounds include nitrogen compounds such as polymethylolated melamine, polymethylolated glycoluril, polymethylolated guanamine, and polymethylolated urea; and compounds in which all or some of active methylol groups (CH₂OH groups bonded to N atoms) in the nitrogen compounds are alkyl-etherified or acyloxylated. Here, examples of the alkyl group constituting the alkyl ether include a methyl group, an ethyl group, a propyl group, and a butyl group, and these groups may be identical to or different from each other. Further, the active methylol group that is not alkyl-etherified or acyloxylated can self-condense within one molecule or can condense between two molecules, resulting in the formation of an oligomer component.

Examples of the crosslinking compound (C1) include crosslinking agents described in JP H06-180501 A, JP 2006-178059 A, and JP 2012-226297 A. Specific examples thereof include melamine-based crosslinking agents such as polymethylolated melamine, hexamethoxymethylmelamine, hexaethoxymethylmelamine, hexapropoxymethylmelamine, and hexabutoxymethylmelamine; glycoluril-based crosslinking agents such as polymethylolated glycoluril, tetramethoxymethylglycoluril, and tetrabutoxymethylglycoluril; guanamine-based crosslinking agents such as compounds, in which guanamine is methylolated, such as 3,9-bis[2-(3,5-diamino-2,4,6-triazaphenyl)ethyl]-2,4,8,10-tetraoxospiro[5.5]undecane and 3,9-bis[2-(3,5-diamino-2,4,6-triazaphenyl) propyl]-2,4,8,10-tetraoxospiro[5.5]undecane, and compounds, in which all or some of active methylol groups in the compounds are alkyl-etherified or acyloxylated. Among these, melamine-based crosslinking agents and guanamine-based crosslinking agents are preferable.

Specifically, the crosslinking compound (C1) is preferably compounds shown below.

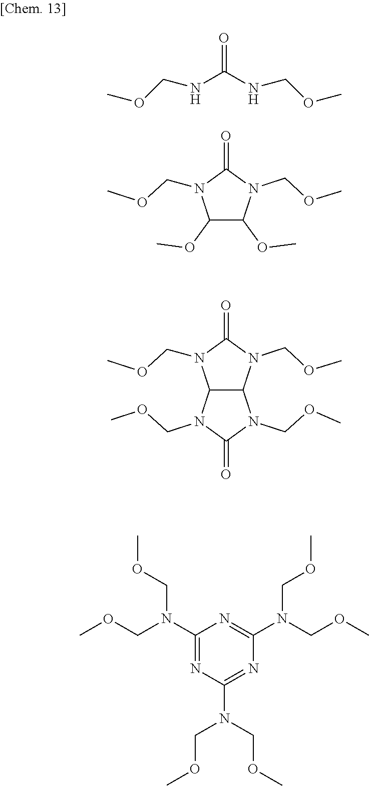

Further, the present composition may further include, as the crosslinking agent (C), an epoxy-based compound (C2) in addition to the crosslinking compound (C1). In the present invention, the epoxy-based compound (C2) is a compound containing an epoxy group (oxirane ring) as a crosslinkable group, and even a compound containing a methylol group or an alkoxymethyl group corresponds to the epoxy-based compound (C2) as long as it contains an epoxy group. That is, the epoxy-based compound (C2) is different from the crosslinking compound (C1). As the crosslinking agent (C2), one type may be used or two or more types may be used in combination.

Examples of the epoxy-based compound (C2) include a phenol novolac-type epoxy resin, a cresol novolac-type epoxy resin, a naphthol novolac-type epoxy resin, a naphthol-phenol co-condensed novolac-type epoxy resin, a naphthol-cresol co-condensed novolac-type epoxy resin, a bisphenol-type epoxy resin, a biphenyl-type epoxy resin, a trisphenol-type epoxy resin, a tetraphenol-type epoxy resin, a phenol-xylylene-type epoxy resin, a naphthol-xylylene-type epoxy resin, a phenol-dicyclopentadiene-type epoxy resin, a phenol aralkyl-type epoxy resin, a naphthol aralkyl-type epoxy resin, a biphenylaralkyl-type epoxy resin, a resorcin-type epoxy resin, a hydroquinone-type epoxy resin, a catechol-type epoxy resin, a dihydroxynaphthalene-type epoxy resin, an alicyclic epoxy resin, and an aliphatic epoxy resin.

As the epoxy-based compound (C2), an alicyclic epoxy resin or an aliphatic epoxy resin is preferable from the viewpoint of solvent solubility, and specific examples of such an epoxy-based compound (C2) include pentaerythritol glycidyl ether (examples of commercial products; trade name: DENACOL EX411 manufactured by Nagase Chemtech Corporation), trimethylolpropane polyglycidyl ether (examples of commercial products; trade names: DENACOL EX321 and 321L manufactured by Nagase ChemteX Corporation), glycerol polyglycidyl ether (examples of commercial products; trade names: DENACOL EX313 and EX314 manufactured by Nagase ChemteX Corporation), neopentyl glycol diglycidyl ether (examples of commercial products; trade name: DENACOL EX211 manufactured by Nagase ChemteX Corporation), ethylene/polyethylene glycol diglycidyl ether (examples of commercial products; trade names: DENACOL EX810 and 850 manufactured by Nagase ChemteX Corporation), propylene/polypropylene glycol diglycidyl ether (trade names: DENACOL EX911, 941, and 920 manufactured by Nagase ChemteX Corporation), 1,6-hexanediol diglycidyl ether (examples of commercial products; trade name: DENACOL EX212 manufactured by Nagase ChemteX Corporation), sorbitol polyglycidyl ether (examples of commercial products; trade names: DENACOL EX611, EX612, EX614, EX614B, and EX610U manufactured by Nagase Chemtech Corporation), propylene glycol diglycidyl ether (examples of commercial products; trade name: EPOLITE 70P manufactured by Kyoeisha Co., LTD.), and trimethylolpropane triglycidyl ether (examples of commercial products; trade name: EPOLITE 100MF manufactured by Kyoeisha Co., LTD.).

Further, as the crosslinking agent (C), another crosslinking agent (C3) other than the crosslinking compound (C1) and the epoxy-based compound (C2) may be used as long as the object and characteristics of the present invention are not impaired. Examples of the another crosslinking agent (C3) include an oxetane ring-containing compound, an oxazoline ring-containing compound, an isocyanate group-containing compound (including blocked ones), a maleimide group-containing compound, and a cyanate ester group-containing compound. As the crosslinking agent (C3), one type may be used or two or more types may be used in combination.

In the present composition, the content of the crosslinking agent (C) is usually 1 to 60 parts by mass, preferably 3 to 50 parts by mass, and more preferably 5 to 40 parts by mass with respect to 100 parts by mass of the polymer (A). When the content of the crosslinking agent (C) is within the above range, a cured film having excellent tensile elongation and PCT resistance is formed. In addition, the composition has excellent curability.

When the epoxy-based compound (C2) is further used as the crosslinking agent (C) in addition to the crosslinking compound (C1), the content of the crosslinking agent (C2) is preferably less than 50 mass % in 100 mass % of the crosslinking agent (C). When the epoxy-based compound (C2) is used, chemical resistance tends to be improved.

### <Solvent (D)>

The present composition includes a solvent (D). Use of the solvent (D) can improve the handleability of the present composition, and adjust the viscosity and storage stability.

The solvent (D) is not particularly limited as long as it is an organic solvent capable of dissolving or dispersing the respective components such as the polymer (A), the compound (B), and the crosslinking agent (C). Examples of the solvent (D) include a ketone solvent, an alcohol solvent, an ether solvent, an ester solvent, an amide solvent, a hydrocarbon solvent, and a lactone solvent. The solvent (D) preferably includes at least one type selected from the group consisting of an amide solvent and a lactone solvent because of excellent solubility.

Examples of the amide solvent include cyclic amide solvents such as N-methyl-2-pyrrolidone (NMP) and dimethylimidazolidinone (DMI), and examples of the lactone solvent include cyclic lactone solvents such as γ-butyrolactone (GBL).

As the solvent (D), one type can be used or two or more types can be used in combination.

The content of the solvent (D) in the present composition is such an amount that the solid content concentration in the composition is usually 10 to 50 mass %.

### <Other Components>

The present composition can include other components in addition to the components described above as long as the object and characteristics of the present invention are not impaired. Examples of the other components include a polymer other than the polymer (A), a low molecular weight phenol compound, a silane coupling agent, a rust inhibitor, an adhesion aid, crosslinked fine particles, a leveling agent, a sensitizer, an inorganic filler, and a quencher.

### <Method for Producing Photosensitive Resin Composition>

The present composition can be produced by uniformly mixing the respective components constituting the present composition by a known method. In addition, in order to remove foreign matter, after uniformly mixing the respective components, the obtained mixture can be filtered with, for example, a filter.

### <Characteristics of Photosensitive Resin Composition>

The patterned resin film obtained by curing the present composition is excellent in tensile elongation and PCT resistance. In order to obtain such characteristics, it is preferable that the i-line transmittance, tensile elongation, and PCT resistance of the polymer to be used are excellent, and the polymer (A) is suitable from this viewpoint. Further, by introducing a hydrophilic highly polar functional group such as a phenolic hydroxy group into the repeating structural unit of the polymer or the polymer terminal in the polymer (A) to be used, in the case of using an aqueous solution containing an alkaline compound as a developer, it becomes easy to appropriately adjust the solubility in the developer, and it becomes possible to adjust the curability by the reaction with the crosslinking agent (C).

### [Resin Film Having Pattern]

The resin film having a pattern (patterned resin film) according to an aspect of the present invention is obtained by curing the present composition described above. Specifically, the patterned resin film obtained by the production method described later can be preferably used as an insulation film (for example, a surface protective film, an interlayer insulation film, or a planarization film) included in a semiconductor circuit board.

### [Method for Producing Resin Film Having Pattern]

The patterned resin film can be produced by a method including a step (1) of forming, on a substrate, a coating film of the present composition, a step (2) of selectively exposing the coating film, and a step (3) of developing the coating film after exposure with an alkaline developer.

### <Step (1)>

In the step (1), the present composition is usually applied onto a substrate so that a thickness of a finally obtained patterned resin film is, for example, 0.1 to 100 μm. The substrate after application of the composition is usually heated at 50 to 140° C. for 10 to 360 seconds using an oven or a hot plate. As such, a coating film formed using the present composition is formed on a substrate.

Examples of the substrate include a silicon wafer, a compound semiconductor wafer, a wafer with a metal thin film, a glass substrate, a quartz substrate, a ceramic substrate, an aluminum substrate, and a substrate having a semiconductor chip on a surface of each of these substrates. Examples of the application method include a dipping method, a spraying method, a bar coating method, a roll coating method, a spin coating method, a curtain coating method, a gravure printing method, a silk screen method, and an inkjet method.

### <Step (2)>

In the step (2), the coating film is selectively exposed using, for example, a contact aligner, a stepper, or a scanner. The expression “selectively” specifically means via a photomask on which a predetermined mask pattern is formed.

Examples of the exposure light include ultraviolet rays and visible rays, and light having a wavelength of 200 to 500 nm (for example, i-line (365 nm)) is usually used. An exposure dose by exposure light varies depending on, for example, the type and blending ratio of each component in the present composition and the thickness of the coating film, and is usually 100 to 1,500 mJ/cm².

### <Step (3)>

In the step (3), the resin film is developed with an alkaline developer, and the exposed portion is dissolved and removed to form a desired patterned on the substrate. Examples of the development method include a shower development method, a spray development method, an immersion development method, and a paddle development method. The development conditions are, for example, 5 to 40° C. and about 1 to 10 minutes. After the resin film is developed with an alkaline developer, the resin film can be washed with water and dried.

Examples of the alkaline developer include an alkaline aqueous solution obtained by dissolving an alkaline compound such as sodium hydroxide, potassium hydroxide, aqueous ammonia, tetramethylammonium hydroxide, or choline in water to a concentration of 1 to 10 mass %. To the alkaline aqueous solution, for example, a water-soluble organic solvent such as methanol or ethanol, and for example, a surfactant can be added in appropriate amounts.

The shape of the pattern in the patterned resin film is not particularly limited as long as it has an irregularity structure, and examples thereof include a line-and-space pattern, a dot pattern, a hole pattern, and a lattice pattern.

### <Step (4)>

The method for producing a patterned resin film according to an aspect of the present invention can include, after the step (3), a step (4) of sufficiently curing the patterned resin film by a heat treatment (post-baking), as necessary, in order to sufficiently exhibit characteristics as an insulation film. The curing conditions are not particularly limited, and depending on the application of the patterned resin film, for example, heating is performed at a temperature of 100 to 350° C. for about 30 minutes to 10 hours.

### [Semiconductor Circuit Board]

Use of the present composition enables the production of a semiconductor circuit board including the patterned resin film. The semiconductor circuit board includes a patterned resin film formed using the present composition described above, and preferably includes a patterned insulation film such as a surface protective film, an interlayer insulation film, or a planarization film, and therefore is useful as a highly reliable circuit board.

### EXAMPLES

Hereinafter, the present invention will be described in more detail based on Examples, but the present invention is not limited to these Examples. In the following description of Examples and others, unless otherwise specified, “part(s)” is used to mean “part(s) by mass”.

### <Synthesis of Polymer>

The weight average molecular weight (Mw) of a polymer obtained in the following synthesis example was measured by a gel permeation chromatography (GPC) method under the following conditions.
Column: product name “TSKgel α-M” (manufactured by TOSOH CORPORATION)
Solvent: N-methyl-2-pyrrolidone (NMP)
Temperature: 40° C.
Detection method: refractive index method:
Standard substance: polystyrene
GPC apparatus: apparatus name “HLC-8320-GPC” manufactured by TOSOH CORPORATION

### [Synthesis Example 1] Synthesis of Polymer (A1)

In a 100 mL three-necked flask equipped with a reflux tube, 6.67 mmol of BzDAxx (manufactured by ENEOS Corporation, the following formula (a1-1)) as an acid anhydride and 19.89 g of N-methyl-2-pyrrolidone (NMP) as a polymerization solvent were placed, and the mixture was stirred and dissolved in a nitrogen atmosphere. Thereto, 5.00 mmol of 2,2-bis(3-amino-4-hydroxyphenyl) hexafluoropropane and 1.67 mmol of 1,3-bis(4-aminophenoxy) propane were added as diamines, and the mixture was stirred at 60° C. for 1 hour and then further stirred at 180° C. for 4 hours. After cooling to room temperature, the reaction solution was poured into 500 mL of distilled water to obtain a white solid. This solid was separated by filtration, washed 3 times with distilled water, and then vacuum-dried at 70° C. for 48 hours to obtain a polymer (A1). The obtained polymer (A1) was analyzed by, for example, ¹H-NMR, and it was found that the imidization rate was 100%. The weight average molecular weight (Mw) of the polymer (A1) was 601,900.

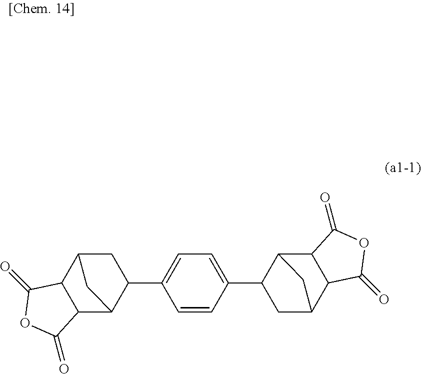 [SMILES: O=C1OC(=O)C2C3CC(CC3c3ccc(C4CC5CC4C4C(=O)OC(=O)C54)cc3)C12]

### [Synthesis Example 2] Synthesis of Polymer (A2)

A polymer (A2) was obtained by an operation similar to that in Synthesis Example 1 except that 5.00 mmol of 2,2-bis(3-amino-4-hydroxyphenyl) hexafluoropropane and 1.67 mmol of ED-900 (manufactured by Huntsman Corporation, the following formula (b2-2)) were used as the diamines and 24.16 g of NMP was used as the polymerization solvent in Synthesis Example 1. The obtained polymer (A2) was analyzed by, for example, ¹H-NMR, and it was found that the imidization rate was 100%. The weight average molecular weight (Mw) of the polymer (A2) was 637,700.

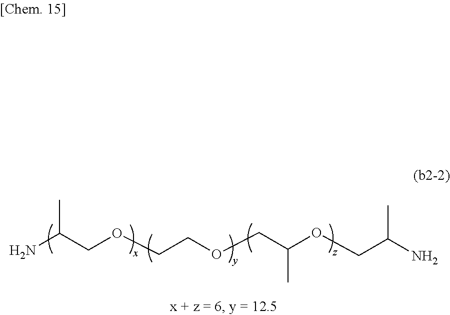

### [Synthesis Example 3] Synthesis of Polymer (A3)

A polymer (A3) was obtained by an operation similar to that in Synthesis Example 1 except that 6.67 mmol of PPHT (manufactured by Nippon Fine Chemical Co., Ltd., the following formula (a1-2)) was used as the acid anhydride and 21.54 g of NMP was used as the polymerization solvent in Synthesis Example 1. The obtained polymer (A3) was analyzed by, for example, ¹H-NMR, and it was found that the imidization rate was 100%. The weight average molecular weight (Mw) of the polymer (A3) was 634, 900.

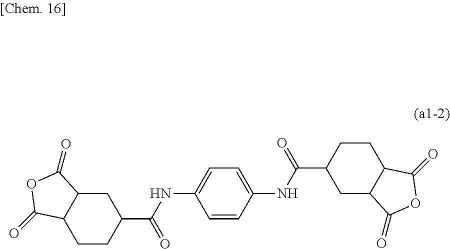 [SMILES: O=C(Nc1ccc(NC(=O)C2CCC3C(=O)OC(=O)C3C2)cc1)C1CCC2C(=O)OC(=O)C2C1]

### [Synthesis Example 4] Synthesis of Polymer (A4)

A polymer (A4) was obtained by an operation similar to that in Synthesis Example 3 except that 4.00 mmol of 2,2-bis(3-amino-4-hydroxyphenyl) hexafluoropropane and 2.67 mmol of 1,3-bis(4-aminophenoxy) propane were used as the diamines and 21.11 g of NMP was used as the polymerization solvent in Synthesis Example 3. The obtained polymer (A4) was analyzed by, for example, ¹H-NMR, and it was found that the imidization rate was 100%. The weight average molecular weight (Mw) of the polymer (A4) was 657, 500.

### [Synthesis Example 5] Synthesis of Polymer (A5)

In a 100 mL three-necked flask equipped with a reflux tube, 7.41 mmol of BzDAxx as an acid anhydride and 25.37 g of NMP as a polymerization solvent were placed, and the mixture was stirred and dissolved in a nitrogen atmosphere. Thereto, 5.00 mmol of 2,2-bis(3-amino-4-hydroxyphenyl) hexafluoropropane and 1.67 mmol of ED-900 as diamines, and 1.48 mmol of 3-aminophenol as a terminal modifier were added, and the mixture was stirred at 60° C. for 1 hour and then further stirred at 180° C. for 4 hours. After cooling to room temperature, the reaction solution was poured into 500 mL of distilled water to obtain a white solid. This solid was separated by filtration, washed 3 times with distilled water, and then vacuum-dried at 70° C. for 48 hours to obtain a polymer (A5). The obtained polymer (A5) was analyzed by, for example, ¹H-NMR, and it was found that the imidization rate was 100%. The weight average molecular weight (Mw) of the polymer (A5) was 29, 200.

### [Synthesis Example 6] Synthesis of Polymer (A6)

A polymer (A6) was obtained by an operation similar to that in Synthesis Example 5 except that 9.26 mmol of PPHT was used as the acid anhydride, 5.00 mmol of 2,2-bis(3-amino-4-hydroxyphenyl) hexafluoropropane and 3.33 mmol of 1,3-bis(4-aminophenoxy) propane were used as the diamines, 1.85 mmol of 3-aminophenol was used as the terminal modifier, and 28.12 g of NMP was used as the polymerization solvent in Synthesis Example 5. The obtained polymer (A6) was analyzed by, for example, ¹H-NMR, and it was found that the imidization rate was 100%. The weight average molecular weight (Mw) of the polymer (A6) was 24,700.

### [Synthesis Example 7] Synthesis of Polymer (A7)

In a 100 mL three-necked flask equipped with a reflux tube, 7.41 mmol of BzDAxx being an acid anhydride, 10.00 g of methanol, and 0.5 mL of pyridine were placed, and the mixture was stirred under reflux for 5 hours in a nitrogen atmosphere. After cooling to room temperature, the mixture was transferred to an eggplant flask, and methanol was distilled off with an evaporator to obtain a half methyl ester of BzDAxx. Subsequently, in a 100 mL three-necked flask A, the total amount of the obtained half methyl ester of BzDAxx was placed together with 20 g of NMP, and the mixture was stirred and dissolved in a nitrogen atmosphere, and cooled in an ice bath. After addition of 15.56 mmol of thionyl chloride, the ice bath was removed, followed by stirring at 50° C. for 1 hour. Then, to another 100 mL three-necked flask B, 5.00 mmol of 2,2-bis(3-amino-4-hydroxyphenyl) hexafluoropropane and 1.67 mmol of 1,3-bis(4-aminophenoxy) propane as diamines and 1.48 mmol of 3-aminophenol as a terminal modifier were added together with 15.00 g of NMP and 0.5 g of pyridine, and the mixture was stirred and dissolved in a nitrogen atmosphere, and cooled in an ice bath. The contents of the flask A cooled to room temperature were transferred to the flask B with a Teflon (registered trademark) tube and nitrogen, then the ice bath was removed, followed by stirring at room temperature for 3 hours. The reaction solution was poured into 500 mL of distilled water to obtain a white solid. This solid was separated by filtration, washed 3 times with distilled water, and then vacuum-dried at 70° C. for 48 hours to obtain a polymer (A7). The obtained polymer (A7) was analyzed by, for example, ¹H-NMR, and it was found that the methyl esterification rate was 100%. The weight average molecular weight (Mw) of the polymer (A7) was 27, 800.

### [Synthesis Example 8] Synthesis of Polymer (A8)

A polymer (A8) was obtained by an operation similar to that in Synthesis Example 6 except that 28.12 g of 1,3-dimethyl-2-imidazolidinone (DMI) was used as the polymerization solvent in Synthesis Example 6. The obtained polymer (A8) was analyzed by, for example, ¹H-NMR, and it was found that the imidization rate was 100%. The weight average molecular weight (Mw) of the polymer (A8) was 24,000.

### [Synthesis Example 9] Synthesis of Polymer (A9)

In a 100 mL three-necked flask equipped with a connecting tube with a cock and a reflux tube, 9.26 mmol of PPHT as an acid anhydride and 28.12 g of γ-butyrolactone (GBL) as a polymerization solvent were placed, and the mixture was stirred and suspended in a nitrogen atmosphere. Thereto, 5.00 mmol of 2,2-bis(3-amino-4-hydroxyphenyl) hexafluoropropane and 3.33 mmol of 1,3-bis(4-aminophenoxy) propane as diamines, and 1.85 mmol of 3-aminophenol as a terminal modifier were added, and the mixture was stirred at 90° C. for 1 hour.

Subsequently, 14.06 g of pyridine as an imidization catalyst was added thereto, and the mixture was stirred at 115° C. for 2 hours and further stirred at 180° C. for 2 hours while pyridine was removed outside the system. After cooling to room temperature, the reaction solution was poured into 500 mL of distilled water to obtain a white solid. This solid was separated by filtration, washed 3 times with distilled water, and then vacuum-dried at 70° C. for 48 hours to obtain a polymer (A9). The obtained polymer (A9) was analyzed by, for example, ¹H-NMR, and it was found that the imidization rate was 100%. The weight average molecular weight (Mw) was 23,900.

### [Synthesis Example 10] Synthesis of Polymer (A10)

A polymer (A10) was obtained by an operation similar to that in Synthesis Example 6 except that 6.95 mmol of PPHT and 2.31 mmol of 4,4′-oxydiphthalic anhydride were used as the acid anhydride in Synthesis Example 6. The obtained polymer (A10) was analyzed by, for example, ¹H-NMR, and it was found that the imidization rate was 100%. The weight average molecular weight (Mw) of the polymer (A10) was 25,100.

### [Synthesis Example 11] Synthesis of Polymer (A11)

A polymer (A11) was obtained by an operation similar to that in Synthesis Example 6 except that 9.26 mmol of PPHT was used as the acid anhydride, 5.00 mmol of 2,2-bis(3-amino-4-hydroxyphenyl) hexafluoropropane, 2.50 mmol of 1,3-bis(4-aminophenoxy) propane, and 0.83 mmol of 1,3-bis(3-aminopropyl)tetramethyldisiloxane were used as the diamines in Synthesis Example 6. The obtained polymer (A11) was analyzed by, for example, ¹H-NMR, and it was found that the imidization rate was 100%. The weight average molecular weight (Mw) of the polymer (A11) was 23,200.

### [Comparative Synthesis Example 1] Synthesis of Polymer (RA1)

In a 100 mL three-necked flask equipped with a reflux tube, 12.00 mmol of 4,4′-oxydiphthalic anhydride as an acid anhydride and 32.47 g of NMP as a polymerization solvent were placed, and the mixture was stirred and dissolved in a nitrogen atmosphere. Thereto, 12.00 mmol of 2,2-bis(3-amino-4-hydroxyphenyl) hexafluoropropane was added as a diamine, and the mixture was stirred at 60° C. for 1 hour and then further stirred at 180° C. for 4 hours. After cooling to room temperature, the reaction solution was poured into 700 mL of distilled water to obtain a white solid. This solid was separated by filtration, washed 3 times with distilled water, and then vacuum-dried at 70° C. for 48 hours to obtain a polymer (RA1). The obtained polymer (RA1) was analyzed by, for example, ¹H-NMR, and it was found that the imidization rate was 100%. The weight average molecular weight (Mw) of the polymer (RA1) was 871, 400.

### [Comparative Synthesis Example 2] Synthesis of Polymer (RA2)

A polymer (RA2) was obtained by an operation similar to that in Comparative Synthesis Example 1 except that 15.00 mmol of 4,4′-oxydiphthalic anhydride was used as the acid anhydride, 11.25 mmol of 2,2-bis(3-amino-4-hydroxyphenyl) hexafluoropropane and 3.75 mmol of 1,3-bis(4-aminophenoxy) propane were used as the diamines, and 38.97 g of NMP was used as the polymerization solvent in Comparative Synthesis Example 1. The obtained polymer (RA2) was analyzed by, for example, ¹H-NMR, and it was found that the imidization rate was 100%. The weight average molecular weight (Mw) of the polymer (RA2) was 969, 700.

### [Comparative Synthesis Example 3] Synthesis of Polymer (RA3)

A polymer (RA3) was obtained by an operation similar to that in Comparative Synthesis Example 2 except that 15.00 mmol of 4,4′-(hexafluoroisopropylidene)diphthalic anhydride was used as the acid anhydride and 47.01 g of NMP was used as the polymerization solvent in Comparative Synthesis Example 2. The obtained polymer (RA3) was analyzed by, for example, ¹H-NMR, and it was found that the imidization rate was 100%. The weight average molecular weight (Mw) of the polymer (RA3) was 755,900.

### [Comparative Synthesis Example 4] Synthesis of Polymer (RA4)

A polymer (RA4) was obtained by an operation similar to that in Comparative Synthesis Example 2 except that 15.00 mmol of 3,3′,4,4′-biphenyltetracarboxylic dianhydride was used as the acid anhydride and 38.01 g of NMP was used as the polymerization solvent in Comparative Synthesis Example 2. The obtained polymer (RA4) was analyzed by, for example, ¹H-NMR, and it was found that the imidization rate was 100%. The weight average molecular weight (Mw) of the polymer (RA4) was 855,100.

### [Comparative Synthesis Example 5] Synthesis of Polymer (RA5)

A polymer (RA5) was obtained by an operation similar to that in Comparative Synthesis Example 2 except that 15.00 mmol of 1,2,3,4-butanetetracarboxylic dianhydride was used as the acid anhydride and 32.24 g of NMP was used as the polymerization solvent in Comparative Synthesis Example 2. The obtained polymer (RA5) was analyzed by, for example, ¹H-NMR, and it was found that the imidization rate was 100%. The weight average molecular weight (Mw) of the polymer (RA5) was 589,100.

### [Comparative Synthesis Example 6] Synthesis of Polymer (RA6)

A polymer (RA6) was obtained by an operation similar to that in Comparative Synthesis Example 2 except that 15.00 mmol of 1,2,3,4-cyclobutanetetracarboxylic dianhydride was used as the acid anhydride and 32.12 g of NMP was used as the polymerization solvent in Comparative Synthesis Example 2. The obtained polymer (RA6) was analyzed by, for example, ¹H-NMR, and it was found that the imidization rate was 100%. The weight average molecular weight (Mw) of the polymer (RA6) was 634,800.

### [Comparative Synthesis Example 7] Synthesis of Polymer (RA7)

A polymer (RA7) was obtained by an operation similar to that in Comparative Synthesis Example 2 except that 15.00 mmol of 1,2,4,5-cyclohexanetetracarboxylic dianhydride was used as the acid anhydride and 33.81 g of NMP was used as the polymerization solvent in Comparative Synthesis Example 2. The obtained polymer (RA7) was analyzed by, for example, ¹H-NMR, and it was found that the imidization rate was 100%. The weight average molecular weight (Mw) of the polymer (RA7) was 845,300.

### [Comparative Synthesis Example 8] Synthesis of Polymer (RA8)

A polymer (RA8) was obtained by an operation similar to that in Comparative Synthesis Example 2 except that 15.00 mmol of dicyclohexyl-3,4,3′,4′-tetracarboxylic dianhydride was used as the acid anhydride and 38.74 g of NMP was used as the polymerization solvent in Comparative Synthesis Example 2. The obtained polymer (RA8) was analyzed by, for example, ¹H-NMR, and it was found that the imidization rate was 100%. The weight average molecular weight (Mw) of the polymer (RA8) was 672,600.

### [Comparative Synthesis Example 9] Synthesis of Polymer (RA9)

A polymer (RA9) was obtained by an operation similar to that in Synthesis Example 6 except that 9.26 mmol of 4,4′-oxydiphthalic anhydride was used as the acid anhydride in Synthesis Example 6. The obtained polymer (RA9) was analyzed by, for example, ¹H-NMR, and it was found that the imidization rate was 100%. The weight average molecular weight (Mw) of the polymer (RA9) was 24,000.

The obtained polymers were evaluated as follows.

### <<Tensile Elongation>>

A 20 mass % NMP solution of the polymer obtained in Synthesis Example or Comparative Synthesis Example was applied onto a substrate with a release material, and then dried by heating at 200° C. for 1 hour (provided that, the polymer (A7) was heated at 300° C. for 1 hour) using an oven to prepare a coating film having a film thickness of 20 μm.

The coating film after heating by post-baking was peeled off from the substrate with a release material to obtain a resin film having a thickness of 20 μm. The obtained resin film was cut into a strip shape of 5 cm long 0.5 cm wide to prepare a tensile test piece. The tensile×elongation at break (%) of the tensile test piece was measured by a tensile compression tester (product name “AGS-500 NX”, manufactured by Shimadzu Corporation). The measurement conditions are as follows: chuck distance=2.5 cm, pulling speed=5 mm/min, and measurement temperature=23° C. The average value of the five measured values was defined as an “elongation (polymer)”, and evaluated according to the following criteria.
◯: The elongation was 50% or more.
X: The elongation was less than 50% or unmeasurable.

### <<PCT Resistance>>

The tensile test piece prepared above was exposed to an environment of 130° C./85% RH/96 hr. The test piece after exposure was dissolved in NMP, and the weight average molecular weight (Mw) was measured under measurement conditions similar to those for the Mw of the polymer by the GPC method. The Mw after polymer synthesis was defined as “Mw (initial value)”, and the Mw of the test piece after the PCT test was defined as “Mw (after PCT test)”.

From the Mw (initial value) and the Mw (after PCT test) measured above, the “molecular weight change” was calculated according to the following formula: “Mw (initial value)−Mw (after PCT test)”/“Mw (initial value)”×100=molecular weight change (%), and evaluated according to the following criteria.
◯: The molecular weight change is less than 30%.
X: The molecular weight change is 30% or more or unmeasurable
   <<i-Line Transmittance>>

A 20 mass % NMP solution of the polymer obtained in Synthesis Example or Comparative Synthesis Example was applied onto a glass substrate, and then heated at 200° C. for 1 hour (provided that, the polymer (A7) was heated at 300° C. for 1 hour) using an oven to prepare a coating film having a film thickness of 10 μm.

The transmittance of the prepared coating film at a wavelength of 365 nm was measured using a spectrophotometer (model “SolidSpec-3700” manufactured by Shimadzu Corporation) and evaluated according to the following criteria.
◯: The transmittance is 80% or more
X: The transmittance is less than 80% or unmeasurable

The types and amounts of the monomers used in Synthesis Examples 1 to 11 and Comparative Synthesis Examples 1 to 9, various physical properties of the obtained polymers, and the results of the various evaluations are shown in the following Table 1-1 and Table 1-2.

TABLE 1-1

| | | Synthesis | Synthesis | Synthesis | Synthesis | Synthesis | Synthesis |
|---|---|---|---|---|---|---|---|
| | | Example | Example | Example | Example | Example | Example |
| | | 1 | 2 | 3 | 4 | 5 | 6 |
| Polymer | | A1 | A2 | A3 | A4 | A5 | A6 |
| Acid | a1-1 | 50.0 | 50.0 | — | — | 47.6 | — |
| anhydride | a1-2 | — | — | 50.0 | 50.0 | — | 47.6 |
| (mol %) | a2-1 | — | — | — | — | — | — |
| | a2-2 | — | — | — | — | — | — |
| | a2-3 | — | — | — | — | — | — |
| | a2-4 | — | — | — | — | — | — |
| | a2-5 | — | — | — | — | — | — |
| | a2-6 | — | — | — | — | — | — |
| | a2-7 | — | — | — | — | — | — |
| Diamine | b1-1 | 37.5 | 37.5 | 37.5 | 30.0 | 32.1 | 25.7 |
| (mol %) | b2-1 | 12.5 | — | 12.5 | 20.0 | — | 17.2 |
| | b2-2 | — | 12.5 | — | — | 10.8 | — |
| | b2-3 | — | — | — | — | — | — |
| Terminal | 3- | — | — | — | — | 9.5 | 9.5 |
| modifier | aminophenol | | | | | | |
| (mol %) | | | | | | | |

| | | | | | | |
|---|---|---|---|---|---|---|
| Polymerization solvent | NMP | NMP | NMP | NMP | NMP | NMP |
| type | | | | | | |
| Mw | 601,900 | 637,700 | 634,900 | 657,500 | 29,200 | 24,700 |
| Imidization rate (%) | 100 | 100 | 100 | 100 | 100 | 100 |
| Methyl esterification rate | — | — | — | — | — | — |
| (%) | | | | | | |
| Polyimide/polyimide | Polyimide | Polyimide | Polyimide | Polyimide | Polyimide | Polyimide |
| precursor | | | | | | |
| i-line transmittance | ∘ | ∘ | ∘ | ∘ | ∘ | ∘ |
| Tensile elongation | ∘ | ∘ | ∘ | ∘ | — | — |
| PCT resistance | ∘ | ∘ | ∘ | ∘ | ∘ | ∘ |

| | | Synthesis | Synthesis | Synthesis | Synthesis | Synthesis |
|---|---|---|---|---|---|---|
| | | Example | Example | Example | Example | Example |
| | | 7 | 8 | 9 | 10 | 11 |
| Polymer | | A7 | A8 | A9 | A10 | A11 |
| Acid | a1-1 | 47.6 | — | — | — | — |
| anhydride | a1-2 | — | 47.6 | 47.6 | 35.8 | 47.6 |
| (mol %) | a2-1 | — | — | — | 11.9 | — |
| | a2-2 | — | — | — | — | — |
| | a2-3 | — | — | — | — | — |
| | a2-4 | — | — | — | — | — |
| | a2-5 | — | — | — | — | — |
| | a2-6 | — | — | — | — | — |
| | a2-7 | — | — | — | — | — |
| Diamine | b1-1 | 32.1 | 25.7 | 25.7 | 25.7 | 25.7 |
| (mol %) | b2-1 | 10.8 | 17.2 | 17.2 | 17.1 | 12.9 |
| | b2-2 | — | — | — | — | — |
| | b2-3 | — | — | — | — | 4.3 |
| Terminal | 3- | 9.5 | 9.5 | 9.5 | 9.5 | 9.5 |
| modifier | aminophenol | | | | | |
| (mol %) | | | | | | |

| | | | | | |
|---|---|---|---|---|---|
| Polymerization solvent | NMP | DMI | GBL | NMP | NMP |
| type | | | | | |
| Mw | 27,800 | 24,000 | 23,900 | 25,100 | 23,200 |
| Imidization rate (%) | — | 100 | 100 | 100 | 100 |
| Methyl esterification rate | 100 | — | — | — | — |
| (%) | | | | | |
| Polyimide/polyimide | Polyimide | Polyimide | Polyimide | Polyimide | Polyimide |
| precursor | precursor | | | | |
| i-line transmittance | ∘ | ∘ | ∘ | ∘ | ∘ |
| Tensile elongation | ∘ | — | — | — | — |
| PCT resistance | ∘ | ∘ | ∘ | ∘ | ∘ |

TABLE 1-2

| | | Compar- | Compar- | Compar- | Compar- | Compar- | Compar- | Compar- | Compar- | Compar- |
|---|---|---|---|---|---|---|---|---|---|---|
| | | ative | ative | ative | ative | ative | ative | ative | ative | ative |
| | | Synthesis | Synthesis | Synthesis | Synthesis | Synthesis | Synthesis | Synthesis | Synthesis | Synthesis |
| | | Example 1 | Example 2 | Example 3 | Example 4 | Example 5 | Example 6 | Example 7 | Example 8 | Example 9 |
| Polymer | | RA1 | RA2 | RA3 | RA4 | RA5 | RA6 | RA7 | RA8 | RA9 |
| Acid | a1-1 | — | — | — | — | — | — | — | — | — |
| anhydride | a1-2 | — | — | — | — | — | — | — | — | — |
| (mol %) | a2-1 | 50.0 | 50.0 | — | — | — | — | — | — | 47.6 |
| | a2-2 | — | — | 50.0 | — | — | — | — | — | — |
| | a2-3 | — | — | — | 50.0 | — | — | — | — | — |
| | a2-4 | — | — | — | — | 50.0 | — | — | — | — |
| | a2-5 | — | — | — | — | — | 50.0 | — | — | — |
| | a2-6 | — | — | — | — | — | — | 50.0 | — | — |
| | a2-7 | — | — | — | — | — | — | — | 50.0 | — |
| Diamine | b1-1 | 50.0 | 37.5 | 37.5 | 37.5 | 37.5 | 37.5 | 37.5 | 37.5 | 25.7 |
| (mol %) | b2-1 | — | 12.5 | 12.5 | 12.5 | 12.5 | 12.5 | 12.5 | 12.5 | 17.2 |
| | b2-2 | — | — | — | — | — | — | — | — | — |
| | b2-3 | — | — | — | — | — | — | — | — | — |
| Terminal | 3- | — | — | — | — | — | — | — | — | 9.5 |
| modifier | aminophenol | | | | | | | | | |
| (mol %) | | | | | | | | | | |

| | | | | | | | | | |
|---|---|---|---|---|---|---|---|---|---|
| Polymerization solvent | NMP | NMP | NMP | NMP | NMP | NMP | NMP | NMP | NMP |
| type | | | | | | | | | |
| Mw | 871,400 | 969,700 | 755,900 | 855,100 | 589,100 | 634,800 | 845,300 | 672,600 | 24,000 |
| Imidization rate (%) | 100 | 100 | 100 | 100 | 100 | 100 | 100 | 100 | 100 |
| Methyl esterification rate | — | — | — | — | — | — | — | — | — |
| (%) | | | | | | | | | |
| Polyimide/polyimide | Polyimide | Polyimide | Polyimide | Polyimide | Polyimide | Polyimide | Polyimide | Polyimide | Polyimide |
| precursor | | | | | | | | | |
| i-line transmittance | X | X | X | X | ◯ | ◯ | ◯ | ◯ | X |
| Tensile elongation | X | ◯ | X | ◯ | X | X | X | X | — |
| PCT resistance | X | X | X | X | ◯ | ◯ | ◯ | ◯ | X |

The details of the acid anhydrides and diamines used in Table 1-1 and Table 1-2 are shown below.

### Acid Anhydride

(a1-1): BzDAxx (manufactured by ENEOS Corporation)
(a1-2): PPHT (manufactured by Nippon Fine Chemical Co., Ltd.)
(a2-1): 4,4′-Oxydiphthalic anhydride
(a2-2): 4,4′-(Hexafluoroisopropylidene)diphthalic anhydride
(a2-3): 3,3′,4,4′-Biphenyltetracarboxylic dianhydride
(a2-4): 1,2,3,4-Butanetetracarboxylic dianhydride
(a2-5): 1,2,3,4-Cyclobutanetetracarboxylic dianhydride
(a2-6): 1,2,4,5-Cyclohexanetetracarboxylic dianhydride
(a2-7): Dicyclohexyl-3,4,3′,4′-tetracarboxylic dianhydride

### Diamine

(b1-1): 2,2-Bis(3-amino-4-hydroxyphenyl) hexafluoropropane
(b2-1): 1,3-Bis(4-aminophenoxy) propane
(b2-2): ED-900 (polyether diamine, manufactured by Huntsman Corporation)
(b2-3): 1,3-Bis(3-aminopropyl)tetramethyldisiloxane

### <Production of Photosensitive Resin Composition>

### Examples 1 to 14 and Comparative Examples 1 and 2

The polymers (polymers (A5) to (A11) and (RA9)), the naphthoquinonediazide compound, the crosslinking agent, and other components shown in the following Table 2 were uniformly mixed in the amounts shown in Table 2 using the solvent shown in Table 2 so as to have the solid content concentration shown in Table 2, and photosensitive resin compositions of Examples 1 to 14 and Comparative Examples 1 and 2 were produced at the curing temperature and the curing time shown in Table 2. The obtained photosensitive resin compositions were evaluated as follows. The results are shown in Table 2.

### <<Solubility of Exposed Portion>>

A 6-inch silicon wafer was spin-coated with the photosensitive resin composition, which was then heated and dried at 110° C. for 5 minutes using a hot plate to prepare a coating film having a film thickness of 10 μm. Subsequently, the coating film was exposed to an ultraviolet ray from a high-pressure mercury lamp through a photomask using an aligner (model “MA-150” manufactured by SUSS MicroTec SE) so that the exposure dose was 1,000 mJ/cm² using g-line, h-line, and i-line exposure wavelengths. The solubility of the exposed portion in a developer (a tetramethylammonium hydroxide aqueous solution having a concentration of 2.38 wt %) was observed and evaluated according to the following criteria.
◯: The exposed portion was completely dissolved within 120 seconds.
X: The exposed portion was completely dissolved in more than 120 seconds

### <<Tensile Elongation>>

The photosensitive resin composition was applied onto a substrate with a release material, and then, heated at 110° C. for 5 minutes using an oven to prepare a coating film. Subsequently, the entire surface of the coating film was exposed to an ultraviolet ray from a high-pressure mercury lamp using an aligner (model “MA-150” manufactured by Suss MicroTec SE) so that the exposure dose at a wavelength of 365 nm was 500 mJ/cm². Subsequently, heating was performed in a nitrogen atmosphere under heating conditions (curing temperature and curing time) shown in Table 2 using an oven.

The coating film after heating by post-baking was peeled off from the substrate with a release material to obtain a resin film having a thickness of 10 μm. The obtained resin film was cut into a strip shape of 5 cm long×0.5 cm wide to prepare a tensile test piece. The tensile elongation at break (%) of the strip-shaped resin film was measured by a tensile compression tester (product name “AGS-500NX” manufactured by Shimadzu Corporation). The measurement conditions are as follows: chuck distance=2.5 cm, pulling speed=5 mm/min, and measurement temperature=23° C. The average value of the five measured values was defined as an “elongation (composition)”, and evaluated according to the following criteria.
◯◯: The elongation was 50% or more.
◯: The elongation is 30% or more and less than 50%
X: The elongation was less than 30% or unmeasurable.

### <<PCT Resistance>>

The tensile test piece prepared above was subjected to atmospheric reflow (highest temperature: 260° C.) 3 times, and then exposed to an environment of 130° C./85% RH/96 hr. The tensile elongation of the test piece after exposure was measured in the same manner as in the “elongation (composition)”, and evaluated according to the following criteria.
◯: The elongation was 20% or more.
X: The elongation was less than 20% or unmeasurable.

TABLE 2

| | | Example 1 | Example 2 | Example 3 | Example 4 | Example 5 | Example 6 | Example 7 | Example 8 |
|---|---|---|---|---|---|---|---|---|---|
| Polymer (A) | A5 | — | — | — | — | — | — | — | 100 |
| (parts by mass) | A6 | 100 | 100 | 100 | 100 | 100 | 100 | 100 | — |
| | A7 | — | — | — | — | — | — | — | — |
| | A8 | — | — | — | — | — | — | — | — |
| | A9 | — | — | — | — | — | — | — | — |
| | A10 | — | — | — | — | — | — | — | — |
| | A11 | — | — | — | — | — | — | — | — |
| | RA9 | — | — | — | — | — | — | — | — |
| Naphthoquinonediazide | B1 | 25 | 25 | 20 | 35 | 35 | 25 | 25 | 25 |
| compound (B) (parts by | | | | | | | | | |
| mass) | | | | | | | | | |
| Crosslinking compound | C1-1 | 20 | — | — | — | — | — | — | — |
| having methylol group | C1-2 | — | 20 | 15 | 15 | 30 | — | — | 20 |
| or alkoxymethyl group | C1-3 | — | — | — | — | — | 20 | — | — |
| (C1) (parts by mass) | C1-4 | — | — | — | — | — | — | 20 | — |
| Epoxy-based | C2-1 | — | — | — | — | — | — | — | — |
| compound (C2) (parts | C2-2 | — | — | — | — | — | — | — | — |
| by mass) | | | | | | | | | |

| Solvent (D) | | D1 | D1 | D1 | D1 | D1 | D1 | D1 | D1 |
|---|---|---|---|---|---|---|---|---|---|
| Solid content concentration | | 30 | 30 | 30 | 30 | 30 | 30 | 30 | 38 |
| (mass %) | | | | | | | | | |
| Curing temperature (° C.) | | 230 | 230 | 230 | 230 | 230 | 230 | 230 | 230 |
| Curing time (h) | | 1 | 1 | 1 | 1 | 1 | 1 | 1 | 1 |
| Solubility of exposed portion | | ◯ | ◯ | ◯ | ◯ | ◯ | ◯ | ◯ | ◯ |
| Tensile elongation | | ◯◯ | ◯◯ | ◯◯ | ◯ | ◯ | ◯◯ | ◯◯ | ◯ |
| PCT resistance | | ◯ | ◯ | ◯ | ◯ | ◯ | ◯ | ◯ | ◯ |
| | | | | | | | | Comparative | Comparative |
| | | Example 9 | Example 10 | Example 11 | Example 12 | Example 13 | Example 14 | Example 1 | Example 2 |
| Polymer (A) | A5 | 100 | — | — | — | — | — | — | — |
| (parts by mass) | A6 | — | — | — | — | — | — | 100 | — |
| | A7 | — | 100 | — | — | — | — | — | — |
| | A8 | — | — | 100 | — | — | — | — | — |
| | A9 | — | — | — | 100 | — | — | — | — |
| | A10 | — | — | — | — | 100 | — | — | — |
| | A11 | — | — | — | — | — | 100 | — | — |
| | RA9 | — | — | — | — | — | — | — | 100 |
| Naphthoquinonediazide | B1 | 25 | 25 | 25 | 25 | 25 | 25 | 25 | 25 |
| compound (B) (parts by | | | | | | | | | |
| mass) | | | | | | | | | |
| Crosslinking compound | C1- | — | 20 | — | — | — | — | — | 20 |
| having methylol group | C1-2 | 20 | — | 20 | 20 | 20 | 20 | — | — |
| or alkoxymethyl group | C1-3 | — | — | — | — | — | — | — | — |
| (C1) (parts by mass) | C1-4 | — | — | — | — | — | — | — | — |
| Epoxy-based | C2-1 | 10 | — | — | — | — | — | — | — |
| compound (C2) (parts | C2-2 | — | — | — | — | — | — | 20 | — |
| by mass) | | | | | | | | | |

| | | | | | | | | |
|---|---|---|---|---|---|---|---|---|
| Solvent (D) | D1 | D1 | D2 | D3 | D1 | D1 | D1 | D1 |
| Solid content concentration | 40 | 30 | 30 | 30 | 30 | 30 | 30 | 30 |
| (mass %) | | | | | | | | |
| Curing temperature (° C.) | 230 | 300 | 230 | 230 | 230 | 230 | 230 | 230 |
| Curing time (h) | 1 | 1 | 1 | 1 | 1 | 1 | 1 | 1 |
| Solubility of exposed portion | ◯ | ◯ | ◯ | ◯ | ◯ | ◯ | ◯ | X |
| Tensile elongation | ◯ | ◯ | ◯◯ | ◯◯ | ◯◯ | ◯◯ | X | ◯◯ |
| PCT resistance | ◯ | ◯ | ◯ | ◯ | ◯ | ◯ | X | X |

The details of the compound (B), the crosslinking compound (C1), the epoxy-based compound (C2), and the solvent (D) used in Table 2 are shown below.

### Compound (B)

(B1): Condensate of 4,4′-[1-[4-[1-(4-hydroxyphenyl)-1-methylethyl]phenyl]ethylidene]bisphenol and 1,2-naphthoquinonediazide-5-sulfonic acid (molar ratio=1.0: 2.0)

### Crosslinking Compound (C1)

(C1-1): HMOM-TPPA (4,4′-[1-[4-[1-[4-hydroxy-3,5-bis(methoxymethyl)phenyl]-1-methylethyl]phenyl]ethylidene]bis[2,6-bis(methoxymethyl)phenol], manufactured by Honshu Chemical Industry Co., Ltd.)
(C1-2): TMOM-BP (3,3′,5,5′-tetrakis(methoxymethyl)-[1,1′-biphenyl]-4,4′-diol, manufactured by Honshu Chemical Industry Co., Ltd.)
(C1-3): HMOM-TPHAP (4,4′,4″-ethylidenetris[2,6-(methoxymethyl)phenol], manufactured by Honshu Chemical Industry Co., Ltd.)
(C1-4): NIKALAC MW-100 LM (hexamethoxymethylated melamine, manufactured by Sanwa Chemical Co., Ltd.)

### Epoxy-Based Compound (C2)

(C2-1): DENACOL EX-321L (trimethylolpropane polyglycidyl ether, manufactured by Nagase ChemteX Corporation)
(C2-2): EXA-4850-150 (bisphenol A-type epoxy resin, manufactured by DIC Corporation)

### Solvent (D)

(D1): N-methyl-2-pyrrolidone (NMP)
(D2): 1,3-Dimethyl-2-imidazolidinone (DMI)
(D3): γ-Butyrolactone (GBL)

1. A photosensitive resin composition comprising:
(A) a polymer that is at least one selected from the group consisting of a polyimide and a polyimide precursor;
(B) a naphthoquinonediazide compound;
(C1) a crosslinking compound having a methylol group or an alkoxymethyl group; and
(D) a solvent, wherein
the polymer (A) comprises a structural unit (a) derived from an acid anhydride and a structural unit (b) derived from a diamine, and
the structural unit (a) comprises a structural unit (a1) derived from an acid anhydride represented by formula (1) below: 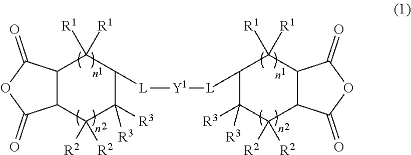
in the formula (1),
L's independently represent a single bond, an ester bond, or an amide bond,
R¹, R², and R³ each independently represent a hydrogen atom or an alkyl group having 1 to 6 carbon atoms, or an alkylene group having 1 to 4 carbon atoms formed by bonding R¹ and R² or R¹ and R³ in a same ring to each other,
n¹ and n² each independently represent an integer of 0 to 3, provided that, in the same ring, at least one of n¹ and n² is an integer of 1 or more,
Y¹ represents a structure represented by formula (Y1) or (Y2) below: 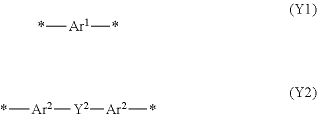
in the formulas (Y1) and (Y2), * represents a bond to L in the formula (1),
Ar¹ and Ar² each independently represent an unsubstituted aromatic ring or a group obtained by removing two hydrogen atoms on an aromatic ring from an aromatic ring substituted with an alkyl group or an alkoxy group having 1 to 6 carbon atoms, and
Y² in the formula (Y2) is at least one group selected from the group consisting of a single bond, an oxygen atom, a sulfur atom, a sulfonyl group, a carbonyl group, a methylene group, a dimethylmethylene group, and a bis(trifluoromethyl)methylene group.

2. The photosensitive resin composition according to claim 1, wherein the polymer (A) has a phenolic hydroxy group at a polymer terminal.

3. The photosensitive resin composition according to claim 1, wherein the structural unit (b) derived from a diamine comprises a structural unit (b1) derived from a diamine having a phenolic hydroxy group.

4. The photosensitive resin composition according to claim 1, further comprising an epoxy-based compound (C2), which is different from the crosslinking compound (C1).

5. A method for producing a resin film having a pattern, the method comprising:
forming, on a substrate, a coating film of the photosensitive resin composition according to claim 1;
selectively exposing the coating film; and
developing the coating film after exposure with an alkaline developer.

6. A resin film having a pattern obtained by curing the photosensitive resin composition according to claim 1.

7. A semiconductor circuit board comprising the resin film having a pattern according to claim 6.
